(19) United States
(12) Patent Application Publication
(10) Pub. No.: US 2012/0188697 A1
(43) Pub. Date: Jul. 26, 2012

(54) DOCKING STATION AND ELECTRONIC APPARATUS USING THE SAME

(75) Inventors: Yung-Hsiang Chen, Taipei City (TW); Hsin Lu, Taipei City (TW); Cheng-Min Huang, Taipei City (TW); Cheng-Jui Lin, Taipei City (TW); Hsiang-Ling Liu, Taipei City (TW); Hsin Yeh, Taipei City (TW)

(73) Assignee: COMPAL ELECTRONICS, INC., Taipei City (TW)

(21) Appl. No.: 13/349,570

(22) Filed: Jan. 13, 2012

Related U.S. Application Data
(60) Provisional application No. 61/435,787, filed on Jan. 25, 2011.

(51) Int. Cl. G06F 1/16; H05K 7/02

(52) U.S. Cl. 361/679.09; 361/807; 361/679.41; 361/679.26

(57) ABSTRACT

An electronic apparatus including a portable device and a docking station is provided. The portable device has a display surface and a first restricting element. The docking station includes a base and a frame. The base has a supporting surface, wherein the portable device is adapted to be placed on the supporting surface. The frame is disposed around the base and has a second restricting element, wherein the frame is adapted to slide related to the base to drive the second restricting element to be aligned to the first restricting element of the portable device placed on the supporting surface, such that the portable device is fixed to the base by means of a magnetic attraction force between the first restricting element and the second restricting element.

### CROSS-REFERENCE TO RELATED APPLICATION

This application claims the priority benefits of U.S. provisional application Ser. No. 61/435,787, filed on Jan. 25, 2011. The entirety of the above-mentioned patent application is hereby incorporated by reference herein and made a part of this specification.

### BACKGROUND OF THE INVENTION

1. Field of the Invention

The present invention generally relates to an electronic apparatus. More particularly, the present invention relates to a docking station and an electronic apparatus using the same.

2. Description of Related Art

Along with the development of technology, portable electronic devices, such as tablet personal computers (tablet PC) and electronic readers (E-Reader), are now in widespread use. In general, control information is input to a conventional tablet personal computer through a touch screen. However, operation convenience of the touch screen does not satisfy all of the user's demands, so that a related docking station is developed accordingly. However, the operation process of the docking station is complicated and the price is high. Therefore, it is an important issue of the computer industry to provide a docking station with a good attachment and improve operation convenience of the docking station and the portable electronic device.

### SUMMARY OF THE INVENTION

The present invention provides an electronic apparatus including a first electronic device and a second electronic device. The first electronic device has a first restricting element. The second electronic device includes a base and a frame. The frame is disposed around the base and has a second restricting element, wherein the frame is adapted to slide related to the base to drive the second restricting element to be fixed to the first restricting element so that the first electronic device fixes to the second electronic device.

According to an embodiment of the present invention, the first electronic device is a portable device and the second electronic device is a docking station.

According to an embodiment of the present invention, the first electronic device is a docking station and the second electronic device is a portable device.

According to an embodiment of the present invention, the portable device has a display surface and the base has a supporting surface, wherein the supporting surface faces to the display surface when the portable device is fixed to the docking station.

According to an embodiment of the present invention, the first restricting element is a magnetic attraction portion or a mechanical latching portion and the second restricting element is a magnetic attraction portion or a mechanical latching portion.

According to an embodiment of the present invention, the magnetic attraction portion is a magnetic conduction element, a permanent magnetic element, or an electro-magnetic element.

According to an embodiment of the present invention, the mechanical latching element is a recess or a protrusion.

According to an embodiment of the present invention, at last one of the first restricting element and the second restricting element is a permanent magnetic element or an electro-magnetic element when the first restricting element and the second restricting element are the magnetic attraction portion.

According to an embodiment of the present invention, the frame has a third restricting element and the base has a fourth restricting element, wherein the third restricting element and the fourth restricting element can be restricted by each other so that a sliding range of the frame relative to the base is limited.

According to an embodiment of the present invention, the docking station further comprises an input interface disposed on the base, wherein the input interface comprises a keyboard module, a touch keyboard, or a touch panel.

According to an embodiment of the present invention, the frame is surrounding to the first electronic device when the second restricting element is fixed to the first restricting element.

According to an embodiment of the present invention, when the first restricting element and the second restricting element are the magnetic attraction portion, the second restricting element is aligned or overlapped to the first restricting element to fix the first electronic device to the second electronic device.

According to an embodiment of the present invention, the frame is adapted to slide related to the base along a direction perpendicular to the supporting surface.

According to an embodiment of the present invention, the portable device has a display surface and the base has a supporting surface, wherein the supporting surface faces to the display surface when the portable device is fixed to the docking station.

According to an embodiment of the present invention, the docking station further comprises an input interface disposed on the base, wherein the input interface comprises a keyboard module, a touch keyboard, or a touch panel.

According to an embodiment of the present invention, the frame is adapted to slide related to the base along a direction perpendicular to the supporting surface.

The present invention further provides an electronic apparatus including a first electronic device having a restricting element and a second electronic device. The frame is disposed around the base and adapted to slide related to the base, wherein the frame is fixed to the restricting element to fix the first electronic device to the second electronic device.

According to an embodiment of the present invention, the first electronic device is a portable device and the second electronic device is a docking station.

According to an embodiment of the present invention, the first electronic device is a docking station and the second electronic device is a portable device.

According to an embodiment of the present invention, the portable device has a display surface and the base has a supporting surface, wherein the supporting surface faces to the display surface when the portable device is fixed to the docking station.

According to an embodiment of the present invention, the restricting element is a magnetic attraction portion and the frame is a magnetic frame.

According to an embodiment of the present invention, the magnetic attraction portion is a magnetic conduction element, a permanent magnetic element, or an electro-magnetic element.

According to an embodiment of the present invention, the frame is surrounding to the first electronic device when the frame is fixed to the restricting element.

According to an embodiment of the present invention, when the restricting element is aligned or overlapped to the frame, the first electronic device is fixed to the second electronic device.

According to an embodiment of the present invention, the frame is adapted to slide related to the base along a direction perpendicular to the supporting surface.

According to an embodiment of the present invention, the portable device has a display surface and the base has a supporting surface, wherein the supporting surface faces to the display surface when the portable device is fixed to the docking station.

In light of the above, through the magnetic attraction portion or the mechanical latching portion disposed on the frame of the second electronic device of the present invention, the first electronic device with a good attachment to the second electronic device is provided. The operation convenience of the second electronic device and the first electronic device is also improved. Furthermore, the second electronic device of the present invention is simple in structure and low cost, since the second electronic device is designed without hinges.

In order to make the aforementioned and other features and advantages of the invention more comprehensible, embodiments accompanying figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view illustrating a portable device and a docking station of an electronic apparatus according to an embodiment of the present invention.

FIG. 2A and FIG. 2B respectively illustrate before and after the portable device of the electronic apparatus in FIG. 1 is fixed to the docking station by means of a magnetic attraction force.

FIG. 3A and FIG. 3B are partial enlarged views respectively showing the flange of the base is restricted in the recess of the frame of the electronic apparatus in FIG. 1 when the portable device is fixed and not fixed to the base.

FIG. 4 is a schematic view illustrating a portable device and a docking station of an electronic apparatus according to another embodiment of the present invention.

FIG. 5A and FIG. 5B respectively illustrate before and after the portable device of the electronic apparatus in FIG. 4 is fixed to the docking station by means of a magnetic attraction force.

### DESCRIPTION OF THE EMBODIMENTS

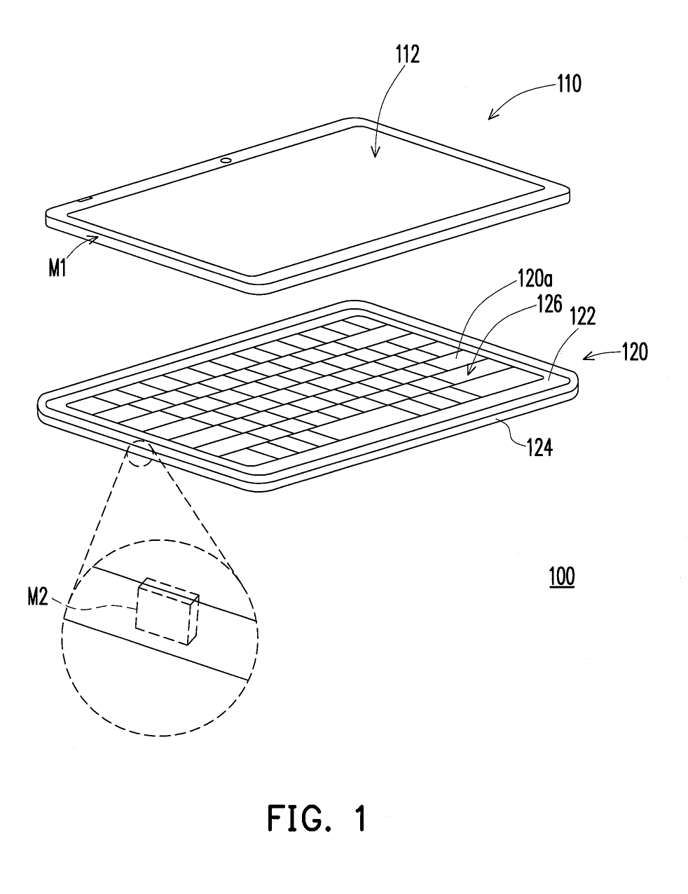

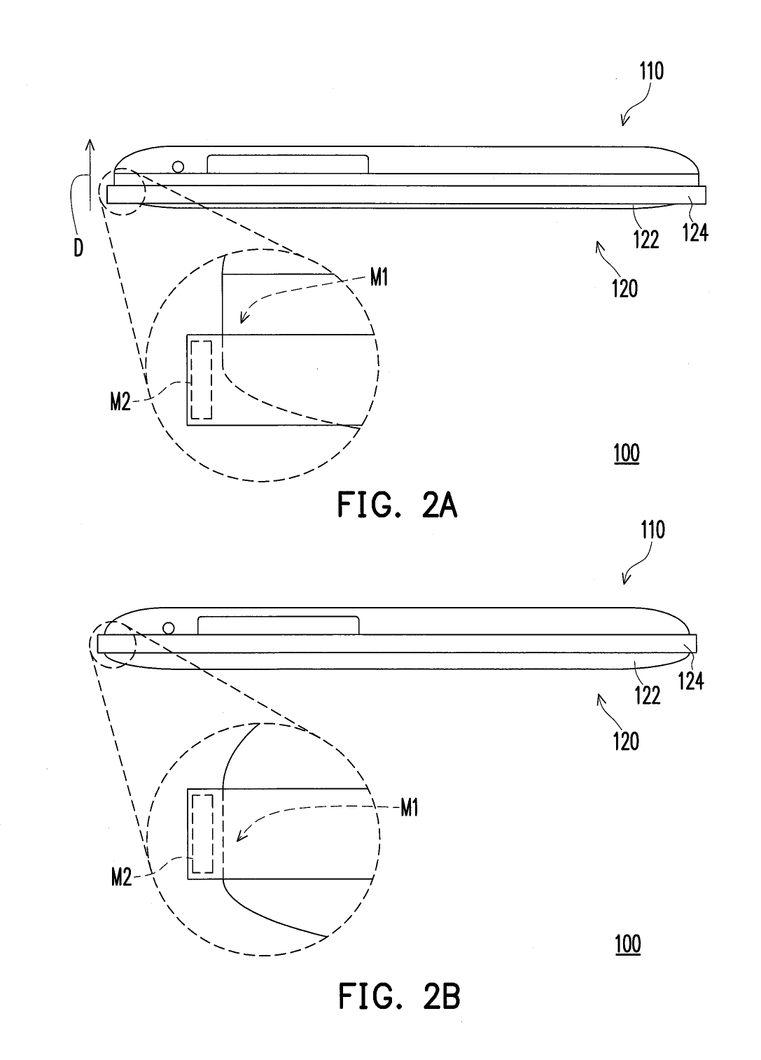

The present invention relates to an electronic apparatus that includes the first electronic device and the second electronic device. The first electronic device has the first restricting element and the second electronic device includes a base and a frame having the second restricting element. The frame is disposed around the base of the second electronic device and adapted to slide related to the base to drive the second restricting element to be fixed to the first restricting element in order to fix the first electronic device to the second electronic device. When the first electronic device is a portable device, the second electronic device is a docking station. When the first electronic device is a docking station and the second electronic device is a portable device. In the embodiment of the present invention, the first electronic device is a portable device, the second electronic device is a docking station, but the present invention is not limited thereto. FIG. 1 is a schematic view illustrating a portable device and a docking station of an electronic apparatus according to an embodiment of the present invention. FIG. 2A and FIG. 2B respectively illustrate before and after the portable device of the electronic apparatus in FIG. 1 is fixed to the docking station by means of a magnetic attraction force. Referring to FIG. 1, FIG. 2A and FIG. 2B, according to an embodiment of the present invention, the electronic apparatus 100 includes a portable device 110 and a docking station 120. The portable device 110 for example, is a tablet personal computer, an electronic reader or any other electronic device having a touch screen.

The portable device 110 has a display surface 112 and the first restricting element M1. In the embodiment, the first restricting element M1 of the portable device 110 is a magnetic attraction portion and can be a magnetic conduction element such as a metal sheet or a magnet. Since most of the portable devices are fabricated with metal materials, the portable device itself 110 is already a magnetic conduction element and no extra process is needed to dispose the magnetic conduction element. In other embodiments, the first restricting element M1 can be a metal element disposed on the portable device 110 or a mechanical latching portion such as a protrusion or a recess, and the present invention is not limited thereto.

In order to satisfy the user's demands of operation convenience of using the portable device 110, a docking station 120 includes a base 122 and a frame 124 is provided. The docking station 120 can include an input interface 120a. In the embodiment, the input interface 120a is a keyboard module as shown in FIG. 1. The input interface 120a also can be a touch keyboard or a touch panel according to different product deigns. The base 122 has a supporting surface 126. The portable device 110 is adapted to be placed on the supporting surface 126 as shown in FIG. 2B to be fixed to the base 122. The frame 124 is disposed around the base 122 and has the second restricting element M2. According to different product designs, the first restricting element and the second restricting element are magnetic attraction portions or mechanical latching portions. When they are magnetic attraction portions, they may be a magnetic conduction element, a permanent magnetic element, or a electro-magnetic element. When they are mechanical latching element, they may be a recess or a protrusion. In the embodiment of the present invention, the first restricting element and the second restricting element are the magnetic attraction portions and at last one of them is a permanent magnetic element or a electro-magnetic element. The claim scope of the present invention is not limited by this embodiment. Herein the frame 124 is adapted to slide related to the base 122 to drive the second restricting element M2 to be aligned or partially overlapping to the first restricting element M1 of the portable device 110 placed on the supporting surface 126, such that the portable device 110 is fixed to the base 122 by means of a magnetic attraction force between the first restricting element M1 and the second restricting element M2 when the first restricting element is a magnetic attraction portion and the second restricting element is the second magnetic attraction portion.

In the steps of fixing the portable device 110 to the docking station 120, first, the portable device 110 is placed on the supporting surface 126 of the base 122 as shown in FIG. 2A; and then the frame 124 is slid upwardly related to the base 122 along a direction D substantially perpendicular to the supporting surface 126 till the second restricting element M2 is aligned or partially overlapping to the first restricting element M1 of the portable device 110 as shown in FIG. 2B; at this moment, the portable device 110 is fixed to the base 122 by means of a magnetic attraction force between the first restricting element M1 and the second restricting element M2.

In this embodiment, the second restricting element M2 is a permanent magnetic element disposed on the frame 124. In other embodiments, the frame 124 can be fabricated with a permanent magnetic material or electro magnetic material to form the second restricting element M2. Furthermore, the second restricting element M2 also can be a mechanical latching portion such as a protrusion or a recess according to different types of the first restricting element, and the present invention is not limited thereto.

More specifically, when the portable device 110 is fixed to the base 122 as shown in FIG. 2B, the display surface 112 (shown in FIG. 1) of the portable device 110 faces to the supporting surface 126 of the base 122. In this way, the docking station 120 can further protect the display surface 112 of the portable device 110 from various contaminations. In addition, when the portable device 110 is fixed to the base 122 as shown in FIG. 2B, the frame 124 is surrounding the portable device 110, such that the second restricting element M2 can be aligned or partially overlapping to the first restricting element M1.

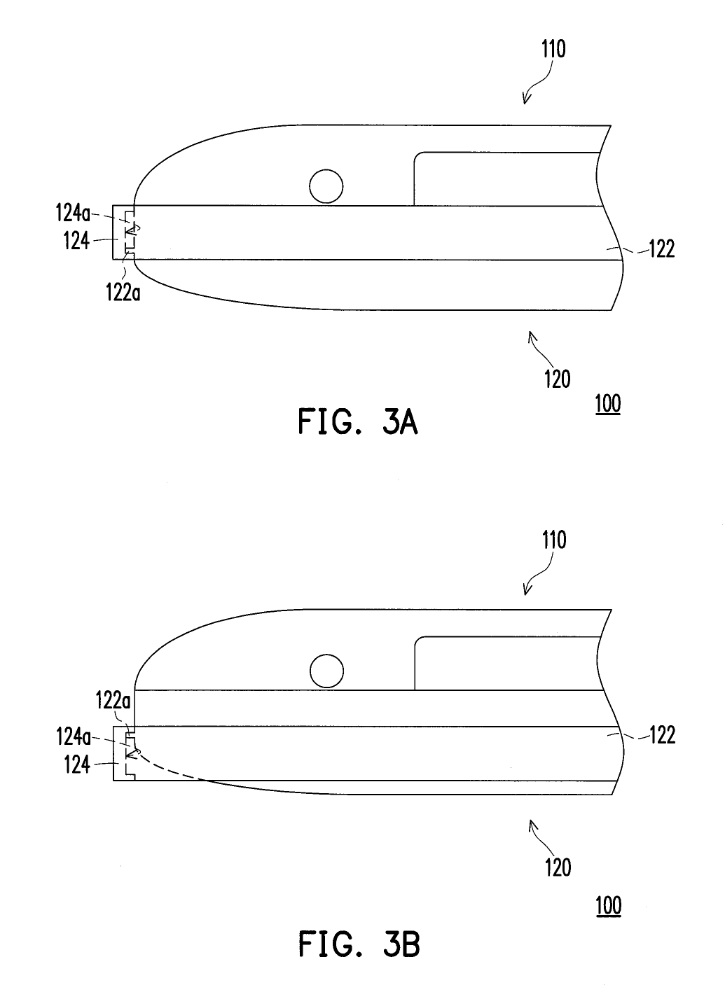

In the embodiment, in order to restrict the frame 124 to slide in a sliding range, some limiting portions can be disposed on the base 122 and the frame 124. For example, FIG. 3A and FIG. 3B are partial enlarged views respectively showing the flange of the base is restricted in the recess of the frame of the electronic apparatus in FIG. 1, and FIG. 3A illustrates the portable device 110 is fixed to the base 122 while FIG. 3B illustrates the portable device 110 is not fixed to the base 122 and just attached to the base 122. Specifically, as shown in FIGS. 3A and 3B, the frame 124 has the third restricting element 124a and the base 122 has the fourth restricting element 122a. The third restricting element can be a recess or a flange and the forth restricting element can be a recess or a flange according to different type of the third restricting element. In the present embodiment, the third restricting element is a recess 124a and the forth restricting element is a flange 122a, and the present invention is not limited thereto. The recess 124a is corresponding to the flange 122a so that the flange 122a can be restricted in the recess 124a to define a sliding range of the frame 124 relative to the base 122. Accordingly, the position of the frame 124 is limited within the sliding range and the frame 124 cannot be departed from the base 122 when the frame 124 slides related to the base 122.

In the embodiment, the flange 122a can be integrally formed with the base 122, and likewise the recess 124a can be integrally formed with the frame 124, but the present invention is not limited thereto.

Furthermore, when the first electronic device is a docking station and the second electronic device is a portable device, the frame is disposed around a base of the portable device and has a second restricting element, wherein the frame is adapted to slide related to the base of the portable device to drive the second restricting element to be fixed to the first restricting element that is on the docking station in order to fix the first electronic device to the second electronic device.

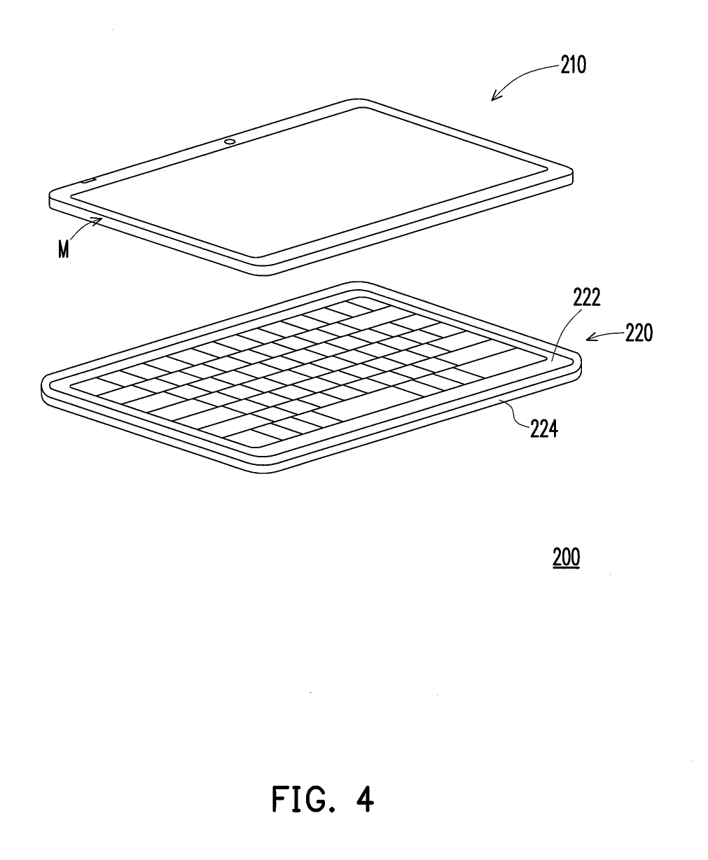

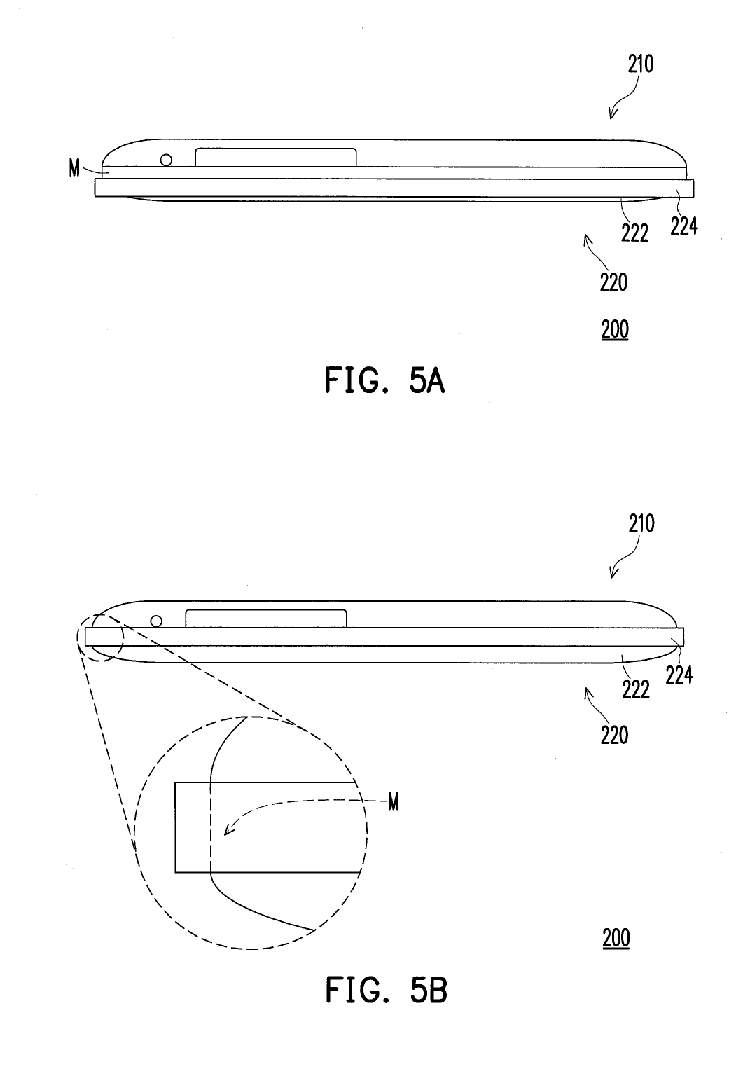

In another embodiment, the electronic apparatus 200 including a first electronic device 210 and a second electronic device 220 is further described as an explanatory embodiment with figures. FIG. 4 is a schematic view illustrating a portable device and a docking station of an electronic apparatus according to another embodiment of the present invention. FIG. 5A and FIG. 5B respectively illustrate before and after the portable device of the electronic apparatus in FIG. 4 is fixed to the docking station by means of a magnetic attraction force. Referring FIG. 4, FIG. 5A and FIG. 5B together, the first electronic device 210 has a restricting element M. The second electronic device 220 includes a base 222 and a frame 224.

Similar to the above mentioned embodiment, the frame 224 is disposed around the base 222 and adapted to slide related to the base 222, wherein the frame 224 is fixed to the restricting element M to fix the first electronic device 210 to the second electronic device 220. When the first electronic device 210 is a portable device, the second electronic device 220 is a docking station. When the first electronic device 210 is a docking station and the second electronic device 220 is a portable device. In this embodiment, the first electronic device 210 is a portable device, the second electronic device 220 is a docking station, but the present invention is not limited thereto.

The difference between the above mentioned embodiment and this embodiment is: the first electronic device 210 has a restricting element M and the restricting element M may be a magnetic attraction portion, whereas the frame 224 may be a magnetic frame. For example, the restricting element M can be the first electronic device 210 it self made of metal which can be attracted by the magnetic frame. And the configuration similar to the above mentioned embodiment is not repeatedly described herein.

In light of the foregoing, through the magnetic attraction portion or the mechanical latching portion disposed on the frame of the second electronic device of the present invention, the first electronic device with a good attachment to the second electronic device is provided. The operation convenience of the second electronic device and the first electronic device is also improved. Furthermore, the second electronic device of the present invention is simple in structure and low cost, since the second electronic device is designed without hinges.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic apparatus, comprising:
a first electronic device having a first restricting element; and
a second electronic device comprising:
a base; and
a frame disposed around the base and having a second restricting element, wherein the frame is adapted to slide related to the base to drive the second restricting element to be fixed to the first restricting element so that the first electronic device fixes to the second electronic device.

2. The electronic apparatus as claimed in claim 1, wherein the first electronic device is a portable device and the second electronic device is a docking station.

3. The electronic apparatus as claimed in claim 1, wherein the first electronic device is a docking station and the second electronic device is a portable device.

4. The electronic apparatus as claimed in claim 2, wherein the portable device has a display surface and the base has a supporting surface, wherein the supporting surface faces to the display surface when the portable device is fixed to the docking station.

5. The electronic apparatus as claimed in claim 1, wherein the first restricting element is a magnetic attraction portion or a mechanical latching portion and the second restricting element is a magnetic attraction portion or a mechanical latching portion.

6. The electronic apparatus as claimed in claim 5, wherein the magnetic attraction portion is a magnetic conduction element, a permanent magnetic element, or an electro-magnetic element.

7. The electronic apparatus as claimed in claim 5, wherein the mechanical latching element is a recess or a protrusion.

8. The electronic apparatus as claimed in claim 6, wherein at last one of the first restricting element and the second restricting element is a permanent magnetic element or an electro-magnetic element when the first restricting element and the second restricting element are the magnetic attraction portion.

9. The electronic apparatus as claimed in claim 1, wherein the frame has a third restricting element and the base has a fourth restricting element, wherein the third restricting element and the fourth restricting element can be restricted by each other so that a sliding range of the frame relative to the base is limited.

10. The electronic apparatus as claimed in claim 2, wherein the docking station further comprises an input interface disposed on the base, wherein the input interface comprises a keyboard module, a touch keyboard, or a touch panel.

11. The electronic apparatus as claimed in claim 1, wherein the frame is surrounding to the first electronic device when the second restricting element is fixed to the first restricting element.

12. The electronic apparatus as claimed in claim 5, wherein when the first restricting element and the second restricting element are the magnetic attraction portion, the second restricting element is aligned or overlapped to the first restricting element to fix the first electronic device to the second electronic device.

13. The electronic apparatus as claimed in claim 4, wherein the frame is adapted to slide related to the base along a direction perpendicular to the supporting surface.

14. The electronic apparatus as claimed in claim 3, wherein the portable device has a display surface and the base has a supporting surface, wherein the supporting surface faces to the display surface when the portable device is fixed to the docking station.

15. The electronic apparatus as claimed in claim 3, wherein the docking station further comprises an input interface disposed on the base, wherein the input interface comprises a keyboard module, a touch keyboard, or a touch panel.

16. The electronic apparatus as claimed in claim 14, wherein the frame is adapted to slide related to the base along a direction perpendicular to the supporting surface.

17. An electronic apparatus, comprising:
a first electronic device having a restricting element; and
a second electronic device comprising:
a base; and
a frame disposed around the base and adapted to slide related to the base, wherein the frame is fixed to the restricting element to fix the first electronic device to the second electronic device.

18. The electronic apparatus as claimed in claim 17, wherein the first electronic device is a portable device and the second electronic device is a docking station.

19. The electronic apparatus as claimed in claim 17, wherein the first electronic device is a docking station and the second electronic device is a portable device.

20. The electronic apparatus as claimed in claim 18, wherein the portable device has a display surface and the base has a supporting surface, wherein the supporting surface faces to the display surface when the portable device is fixed to the docking station.

21. The electronic apparatus as claimed in claim 17, wherein the restricting element is a magnetic attraction portion and the frame is a magnetic frame.

22. The electronic apparatus as claimed in claim 21, wherein the magnetic attraction portion is a magnetic conduction element, a permanent magnetic element, or an electro-magnetic element.

23. The electronic apparatus as claimed in claim 17, wherein the frame is surrounding to the first electronic device when the frame is fixed to the restricting element.

24. The electronic apparatus as claimed in claim 21, wherein when the restricting element is aligned or overlapped to the frame, the first electronic device is fixed to the second electronic device.

25. The electronic apparatus as claimed in claim 20, wherein the frame is adapted to slide related to the base along a direction perpendicular to the supporting surface.

26. The electronic apparatus as claimed in claim 19, wherein the portable device has a display surface and the base has a supporting surface, wherein the supporting surface faces to the display surface when the portable device is fixed to the docking station.
